(19) United States
(12) Patent Application Publication
(10) Pub. No.: US 2025/0386486 A1
(43) Pub. Date: Dec. 18, 2025

(54) DYNAMIC RANDOM ACCESS MEMORY DEVICE HAVING LOGIC CIRCUIT INTEGRATED WITH MEMORY CELLS AND METHOD OF FABRICATING THE SAME

(71) Applicant: IMEC VZW, Leuven (BE)

(72) Inventors: Sylvain Baudot, Woluwe Saint-Lambert (BE); Geert Hellings, Halle (BE)

(21) Appl. No.: 19/235,449

(22) Filed: Jun. 11, 2025

(30) Foreign Application Priority Data
Jun. 12, 2024 (EP) 24181590.1

(51) Int. Cl. H10B 12/00; H10D 1/68; H10D 30/00; H10D 30/43; H10D 62/10; H10D 84/85

(52) U.S. Cl. CPC H10B 12/33; H10B 12/036; H10B 12/038; H10B 12/373; H10B 12/485; H10B 12/50; H10D 1/716; H10D 30/43; H10D 30/502; H10D 62/121; H10D 84/851

(57) ABSTRACT

The disclosed technology relates to dynamic random access memory (DRAM) devices. The disclosed technology provides an integrated DRAM device including a DRAM and a logic circuit configured to control the DRAM. In one aspect, a DRAM device includes a plurality of stacked transistors arranged in a first region of the DRAM device, the stacked transistors being disposed one over another along a stacking direction, and a storage capacitor arranged in a second region of the DRAM device. The first region is positioned above the second region along the stacking direction. One of the plurality of stacked transistors is connected to the storage capacitor to form a DRAM cell of the DRAM, and remaining one or ones of the plurality of stacked transistors forms at least a portion of the logic circuit.

### CROSS-REFERENCE TO RELATED APPLICATIONS

This application claims foreign priority to European Patent Application No. EP 24181590.1, filed Jun. 12, 2024. The contents of each are incorporated by reference herein in its entirety.

### BACKGROUND

### Field

The disclosed technology generally relates to dynamic random access memory (DRAM) devices. In particular, the disclosed technology relates to an integrated DRAM device that comprises a DRAM and a logic circuit configured to control the DRAM. The disclosed technology also relates to a method of fabricating an integrated DRAM device.

### Description of the Related Technology

System-Technology Co-Optimization (STCO) is an approach that aims to optimize both system level design and semiconductor technology. Unlike conventional approaches that optimize components separately, STCO involves simultaneous co-design and co-optimization of the components to leverage synergies that enhance performance and scalability.

In particular, STCO offers potential benefits for future scaling of DRAM devices roadmaps. One such benefit is that STCO can allow integrating DRAMs with logic circuits in integrated DRAM devices. Conventionally, this integration is achieved either by three-dimensional (3D) integration of separate chips or by fabricating the logic circuit on a separate chip area.

However, 3D integration of separate chips is associated with high complexity and requires connecting the DRAM to the logic circuit via through-silicon vias (TSVs). Using separate chips for the DRAM and the logic circuit also results in reduced performance, particularly due to increased timing delays caused by additional routing. Using a separate chip area for fabricating the logic circuit increases chip size and also its manufacturing costs.

### SUMMARY

It is an objective of the present invention to provide a new approach for an integrated DRAM device that integrates a DRAM and a logic circuit configured to control the DRAM. An objective of the invention is to design a DRAM device with reduced complexity. Another objective is to obtain a compact DRAM device. A further objective is to reduce the cost of fabricating the DRAM device. Yet another objective is to reduce timing delay.

Technical objectives, as disclosed herein, can be achieved by the solutions provided in the independent claims. Advantageous implementations are described in the dependent claims.

A first aspect of this disclosure relates to an integrated DRAM device including a DRAM and a logic circuit configured to control the DRAM, wherein the DRAM device comprises: a plurality of stacked transistors arranged in a first region of the DRAM device the stacked transistors being disposed one over another along a stacking direction; and a storage capacitor arranged in a second region of the DRAM device, wherein the first region is arranged above the second region along the stacking direction; wherein one transistor of the plurality of stacked transistors is connected to the storage capacitor to form a DRAM cell of the DRAM, and wherein remaining one or ones of the plurality of stacked transistors forms at least a portion of the logic circuit.

The DRAM device of the first aspect can integrate the DRAM and the logic circuit. For instance, the DRAM and the logic circuit may be monolithically integrated. The DRAM device may not require TSVs to connect the DRAM and the logic circuit. The DRAM may be fabricated directly into a substrate or a substrate layer, on which the logic circuit is fabricated, e.g., by backside integration of the storage capacitor of the DRAM cell into the substrate of the stacked transistors. The substrate may be a wafer.

In this way, the DRAM device can be compact and can have a low-complexity design. No additional area may be required for the DRAM, as it cam be monolithically integrated with the transistors of the logic circuit. Thus, the fabrication costs can be reduced as well. Moreover, by placing the DRAM cell in proximate to the logic circuit, a timing delay can be reduced.

In some embodiments, the stacked transistors may be formed by stacked transistor channels (e.g., made of a semiconductor material), which are surrounded by a gate structure (e.g., a gate-all around (GAA) structure). The stacked transistors may be formed in a conventional way on the wafer or substrate, before the DRAM is processed. The one transistor may be the lowest/bottom-most transistor of the stacked transistors, that is, the one closest to the second region/wafer/substrate.

In some embodiments, the second region may be a substrate layer of the DRAM device, and the storage capacitor may be embedded in the substrate layer.

In this way, a compact DRAM device can be achieved and a fabrication process may be simplified. The integration offers further advantages, such as shorter connections and avoiding vias.

In some embodiments, the one transistor may be connected by a drain thereof to a first metal structure of the storage capacitor.

In some embodiments, the storage capacitor may further comprise a second metal structure, wherein the first metal structure may be arranged above the second metal structure along the stacking direction, and a dielectric layer separating and isolating the second metal structure from the first metal structure.

The two metal structures can function as capacitor plates of the storage capacitor.

In some embodiments, the second metal structure may be connected to a ground line of the DRAM device, and the second region may be arranged above the ground line along the stacking direction.

In some embodiments, the DRAM device may further comprises a bit line contact formed in the second region, wherein the bit line contact may be connected to a source of the one transistor, and may be connected to a bit line of the DRAM device; wherein the second region is arranged above at least a part of the bit line along the stacking direction.

In some embodiments, a gate of the one transistor may be connected to an address line of the DRAM device.

In some embodiments, at least a part of the address line is arranged above the first region along the stacking direction.

In some embodiments, the DRAM device may further comprise a gate contact arranged in the second region, wherein the gate contact may be connected to the gate of the one transistor, and connected to the address line; wherein the second region is arranged above at least a part of the address line along the stacking direction.

In some embodiments, the first region and the second region may be monolithically integrated. This offers advantages of size reduction, improved performance due to shorter connections and lower parasitic resistances and capacitances, lower power consumption, increased reliability, and cost efficiency.

In some embodiments, the stacked transistors may be nanosheet transistors. The remaining one or ones of the plurality of stacked transistors may comprise a set of n-type transistors and a set of p-type transistors of a complementary field effect transistor (CFET).

The nanosheet transistors may be formed by stacked nanosheet (channels) with a gate-all-around (GAA) structure surrounding them. The nanosheet transistors may be formed in a conventional way. Other stacked transistors may be used. The transistors could also be fin field-effect transistors (FinFETs).

A second aspect of this disclosure relates to a method for fabricating an integrated DRAM device including a DRAM and a logic circuit configured to control the DRAM, wherein the method comprises: forming a plurality of stacked transistors in a first region of the DRAM device one above another along a stacking direction; forming a storage capacitor in a second region of the DRAM device, wherein the first region is formed above the second region along the stacking direction; wherein one transistor of the plurality of stacked transistors is connected to the storage capacitor to form a DRAM cell of the DRAM; and wherein remaining one or ones of the plurality of stacked transistors are formed as part of the logic circuit.

In some embodiments, the second region may be a substrate layer; the first region may be formed on a front surface of and above the substrate layer; and the storage capacitor is processed into the substrate layer from a back surface of the substrate layer.

In some embodiments, the storage capacitor may be formed self-aligned with the one transistor, by etching a sacrificial plug adjacent to a source and a drain of the one transistor, and by filling a first metal of the storage capacitor into a space resulting from the etching of the sacrificial plug. The storage capacitor may be formed in proximate to the one transistor, such that the first metal is connected to the source and the drain of the one transistor without using vias.

The self-alignment facilitates the fabrication process, and improves the performance and reliability of the DRAM device.

In some embodiments, the method may further comprise forming a bit line contact and optionally a gate contact in the second region; wherein the bit line contact may be connected to a source of the one transistor, and the gate contact, if present, may be connected to a gate of the one transistor.

The method of the second aspect can achieve substantially the same advantages as described for the DRAM device of the first aspect, and may be extended by respective implementations similar to those described above for the DRAM device of the first aspect.

In summary, the disclosed technology relates to forming a DRAM device that includes a storage capacitor connected to, and may be self-aligned with one of a plurality of stacked transistors, e.g., transistors of a CFET structure. The storage capacitor and the one transistor, e.g. the lowest transistor of the CFET structure, form a DRAM cell of the DRAM, and the other stacked transistors are configured to form a logic circuit that controls the DRAM. The formation of the storage capacitor directly below the stacked transistors enable integration of the DRAM with the logic circuit.

### BRIEF DESCRIPTION OF THE DRAWINGS

The above described aspects and implementations are explained in the following description of embodiments with respect to the enclosed drawings:

FIG. 1 illustrates an example embodiment of a DRAM device.

FIGS. 2-9 illustrate a first example processing sequence for fabricating a DRAM device according to embodiments.

FIGS. 10-17 illustrate a second example processing sequence for fabricating a DRAM device according to embodiments.

FIG. 18 illustrates exemplary implementations and explanation of elements and materials of the DRAM device according to embodiments.

FIG. 19 illustrates a schematic circuit of the DRAM cell.

FIG. 20 illustrates a flow diagram of an example method for fabricating a DRAM device according to embodiments.

### DETAILED DESCRIPTION

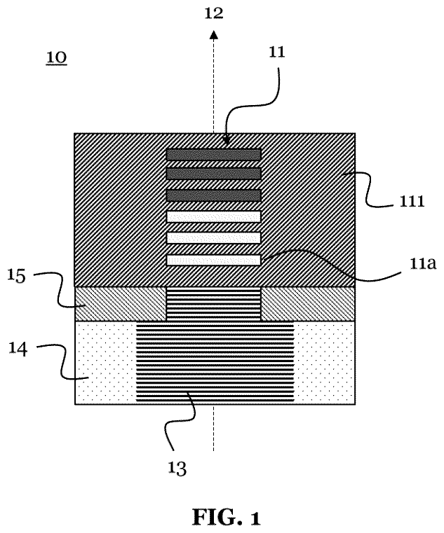

FIG. 1 illustrates an example embodiment of an integrated DRAM device 10. The DRAM device 10 may include a DRAM and a logic circuit. The DRAM and the logic circuit may be integrated. The DRAM may include at least one DRAM cell. The logic circuit can be configured to control the DRAM. For instance, the logic circuit may control at least one of the following operations of the DRAM: address decoding, read/write control, refresh control, and data buffering. For example, address decoding can determine the specific DRAM cell, from which to read or to which to write by decoding an address. Read/write control can manage the timing and control signals for reading data from, or writing data to, the DRAM cells. Refresh control can periodically refresh the data stored in the DRAM cells to prevent data loss due to charge leakage. Data Buffering can handle the transfer of data between the DRAM and, for example, a CPU or other components, ensuring data integrity and proper timing.

The DRAM device 10 may comprise a plurality of stacked transistors 11 arranged in a first region of the DRAM device 10. The plurality of stacked transistors may be disposed along a stacking direction 12. The stacking direction 12 may be a growth direction. The first region may correspond to a region in which a gate-all-around (GAA) structure 111 of the stacked transistors 11 is arranged, e.g., around stacked channels of the transistors 11. The stacked transistors 11 may be nanosheet transistors, i.e., the channels may be nanosheets. The stacked transistors 11 may comprise n-type transistors and p-type transistors (as exemplarily distinguished in FIG. 1 by the different gray scales), and may together form together a complementary field effect transistor (CFET) structure.

The GAA structure 111 may comprise a high dielectric consistent (high-k) material and a high-k metal gate (HKMG) material, for example, titanium nitride (TiN). Additionally, tungsten (W) may be deposited on top of the TiN. Accordingly, the GAA structure 111 may thus comprise and be referred to as HKMG+W. The stacked transistors 11 may include the stacked channels of the transistors 11 and may also include the GAA structure 111, or another gate structure, including a gate dielectric and metal.

The DRAM device 10 may further comprise a storage capacitor 13, which may be arranged in a second region of the DRAM device 10. The second region may be a region of a substrate, referred to herein interchangeably as a substrate or wafer, or a substrate layer 14 (e.g., a layer on a substrate/wafer) of the DRAM device 10. The storage capacitor 13 may be embedded within the substrate layer 14. The storage capacitor 13 may be fabricated by processing from the backside or back surface of the substrate/wafer into the substrate layer 14. The first region may be arranged above the second region along the stacking direction, for instance, the GAA structure 111 may be arranged above the substrate layer 14. The first region and the second region may be monolithically integrated, as shown in FIG. 1.

One transistor 11a of the plurality of stacked transistors 11, for example, the lowest transistor 11a of the stacked transistors 11, i.e., the transistor 11a that is closest to the second region may be connected to the storage capacitor 13. The storage capacitor 13 and the one of the plurality of stacked transistors 11 can form a DRAM cell of the DRAM. Accordingly, FIG. 1 may be considered showing a unit cell of the DRAM device 10. A DRAM typically has more than one DRAM cell, and for each DRAM cell of the DRAM, the unit cell shown in FIG. 1 may be repeated.

Remaining one or ones of the plurality of stacked transistors 11 may be configured to form at least a portion of the logic circuit. This can be the case for each repetition of the unit cell. Accordingly, the logic circuit can comprise many transistors and multiple stacks, which can be used to control the DRAM with all of its DRAM cells. The logic circuit may additionally preform other processing steps of the DRAM device. In some embodiments, the remaining one or ones of the plurality of stacked transistors 11 may include a set of n-type transistors and a set of p-type transistors of a CFET structure.

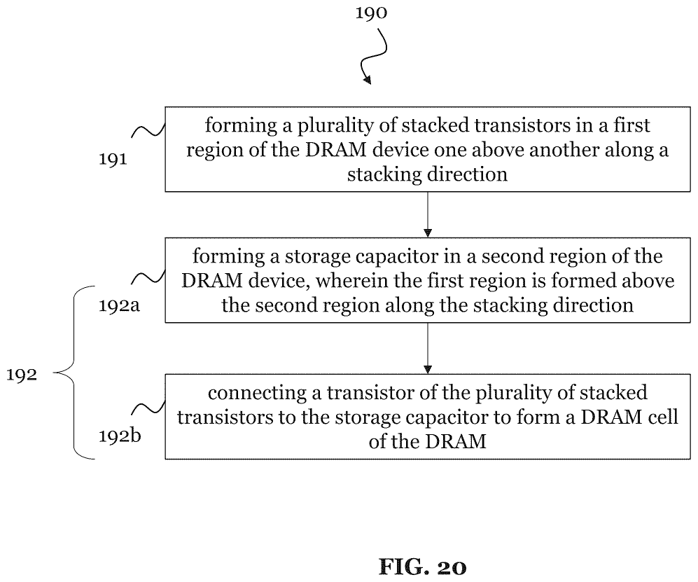

FIG. 20 illustrates a flow diagram of an example method 190 for fabricating the DRAM device 10 according to embodiments. The method 190 can be suitable for fabricating the DRAM device 10 of FIG. 1.

The method may include a step 191 of forming the plurality of stacked transistors 11 in the first region of the DRAM device 10, one above another along the stacking direction 12. The method may 190 further include a step 192, which comprises forming 192a the storage capacitor 13 in the second region of the DRAM device 10, and connecting 192b one of the plurality of stacked transistors 11 to the storage capacitor 13, to form the DRAM cell of the DRAM. Remaining one or ones of the plurality of stacked transistors 11 are configured to form at least a portion of the logic circuit.

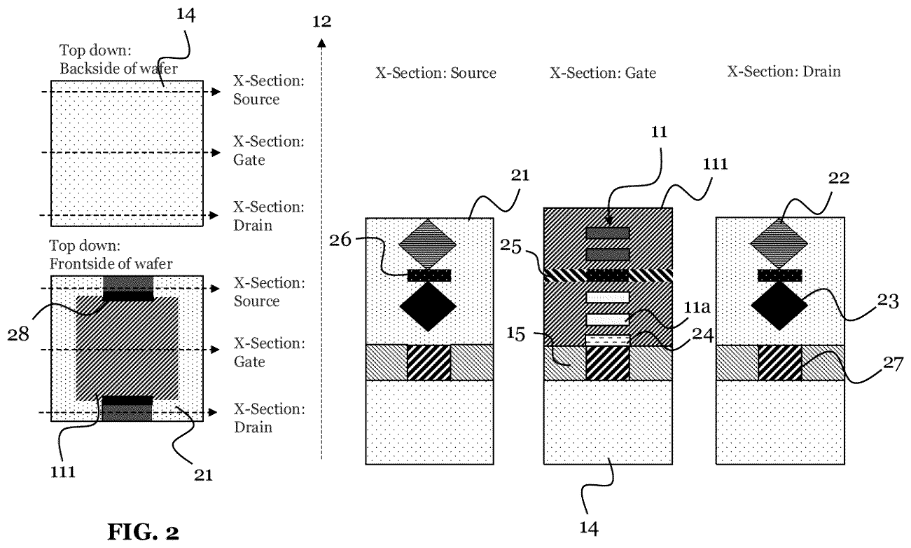

FIGS. 2-9 illustrate a first example processing sequence for fabricating a DRAM device 10 according to embodiments. The first example processing sequence is based on the method 190. The first example processing sequence forms a gate connection from the front side of the wafer/substrate 14.

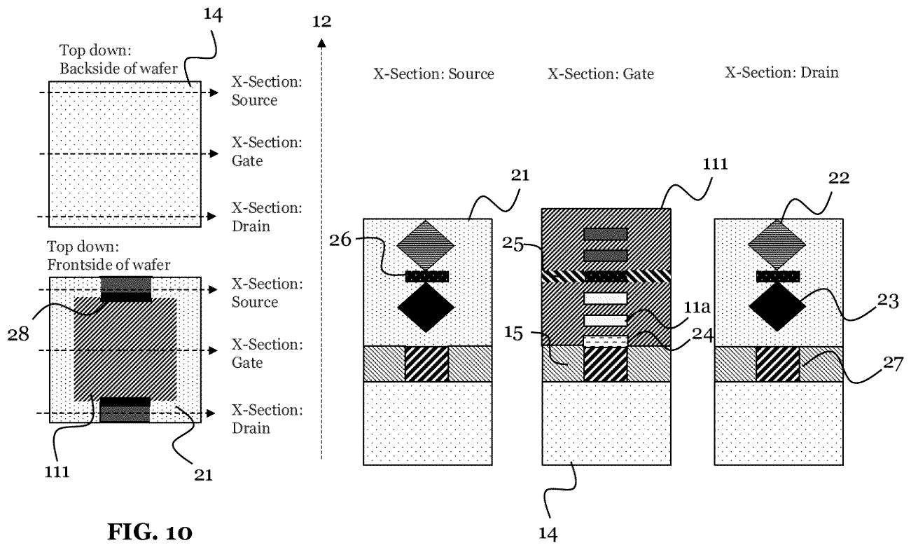

FIGS. 10-17 illustrate a second example processing sequence for fabricating a DRAM device 10 according to embodiments. The second example processing sequence is also based on the method 190. The second example processing sequence, in contrast to the first example processing sequence, forms connections, including the gate connection, from the backside of the wafer/substrate 14.

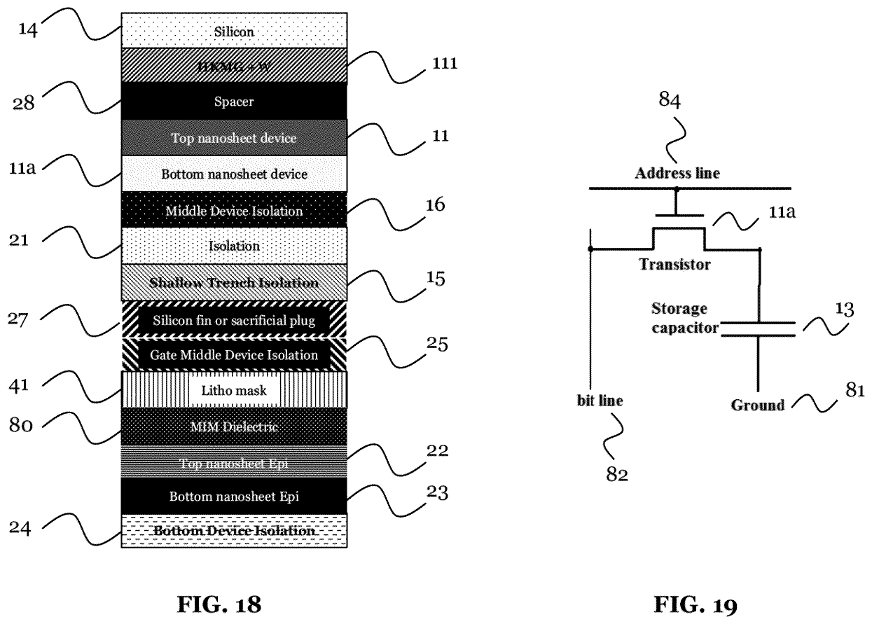

In FIGS. 2-17, various elements of the DRAM device 10, and respective intermediate versions thereof, are indicated with different gray scales and shadings. An exemplary explanation of these elements is shown in FIG. 18, wherein the same gray scales and shadings are used.

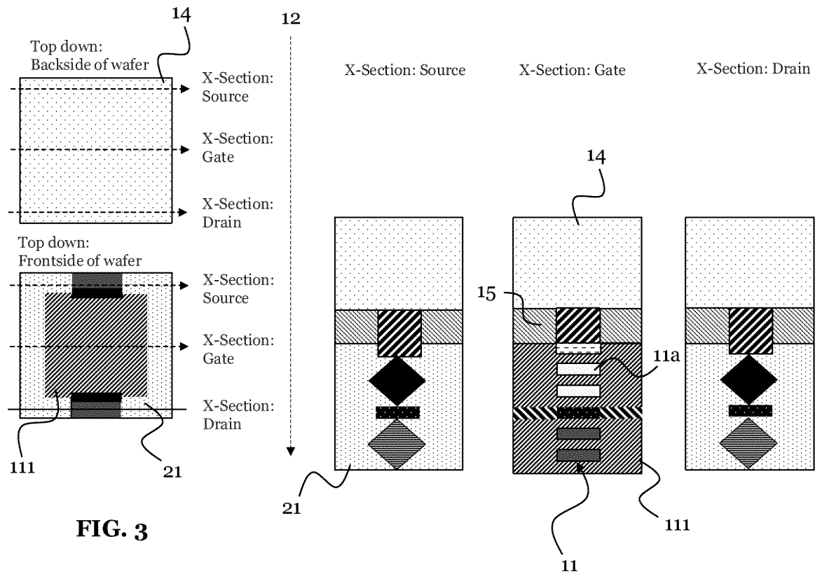

FIG. 2 shows an initial structure for starting a first example processing sequence. The initial structure is shown in various views, particularly, in a top-down view of the backside of the substrate/wafer, in a top-down view of the front side of the substrate/wafer, in a view along a cross-section (X-section) through the source, in a view along a X-section through the gate, and in a view along the X-section through the drain. The same views are used in the FIGS. 3-17 to illustrate the first example processing sequence and a second example processing sequence, respectively.

The initial structure in FIG. 2 includes the substrate 14 (or substrate layer, in any case collectively referred to herein as a wafer), for example made of silicon or silicon-based material, and includes a plurality of stacked transistors 11 formed above the substrate 14. In certain embodiments, a plurality of transistor channels is stacked and the reference sign 11 points to the channels. A GAA structure 111 surrounds the channels. The initial structure may be processed according to conventional processing techniques, for example, nanosheet transistor fabrication processes. Accordingly, the plurality of stacked transistors 11 may—as illustrated in FIG. 2—be stacked nanosheet transistors, and may be formed as a CFET structure, which includes both n-type and p-type nanosheet transistors, illustrated by different grayscale shading. The stacked transistors 11, in certain embodiments, may include top transistors 11 and bottom transistors 11, for example, the bottom-most transistor 11a that is closest to the substrate 14. The top and bottom transistors 11 are separated from each other by a middle device isolation (MDI) 26 and a gate MDI 25. In the example of FIG. 2, the top transistors and bottom transistors form the CFET structure, wherein the transistors have a different majority carrier type, electrons or holes, in the source/drain region and in the channel. The transistors 11 may all be surrounded by the GAA structure 111, which may comprise HKMG+W, as described above. The GAA structure 111 can be further separated from the substrate 14 by a shallow trench isolation (STI) 15, in which a silicon fin or sacrificial plug 27 is formed and is aligned with the stacked transistors 11 or the channels of the stacked transistors 11. The GAA structure 111 may be partly surrounded by an isolation 21. The transistors 11 may additionally be contacted by epitaxial regions (epi-regions) 22 and 23, respectively, for the top and the bottom transistors 11. These epi-regions 22, 23 may be made from highly doped semiconductor material, and are positioned at either end of the transistor channels, to implement source and drain regions. A spacer 28 may be provided between the GAA structure 111 and the source/drain regions of the transistors 11.

FIG. 3 illustrates a first step of the first example processing sequence. In the first step, the initial structure is flipped, and then a partial polish is performed on the backside of the substrate 14.

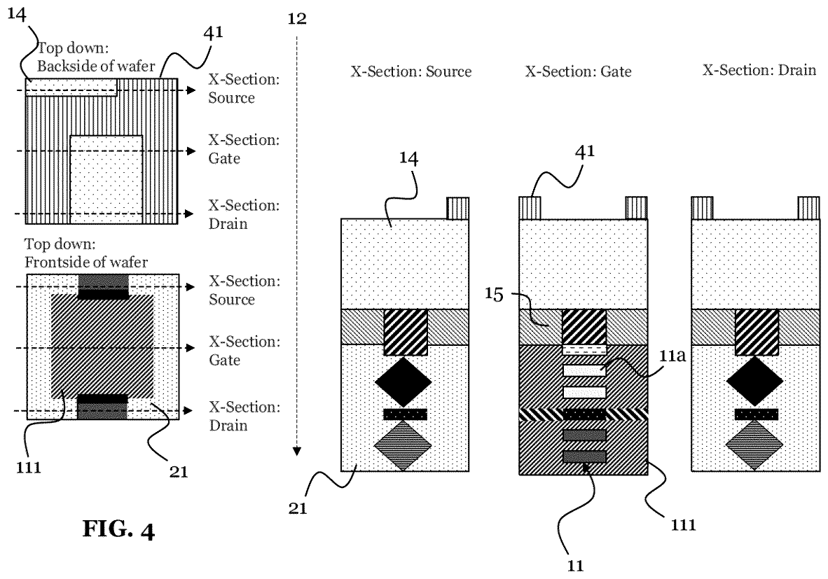

FIG. 4 illustrates a second step of the first example processing sequence. In this second step, lithography is performed, for example, for the purpose of processing a source, gate, and drain contact for the one transistor 11a in a self-aligned manner. The self-alignment is achieved using the sacrificial plug 27. For example, the lithography shape may be lines, as the subsequent etching is self-aligned to the sacrificial plug 27. A first mask material 41 is selectively applied during the lithography, the first mask material 41 is applied to the backside of the substrate 14.

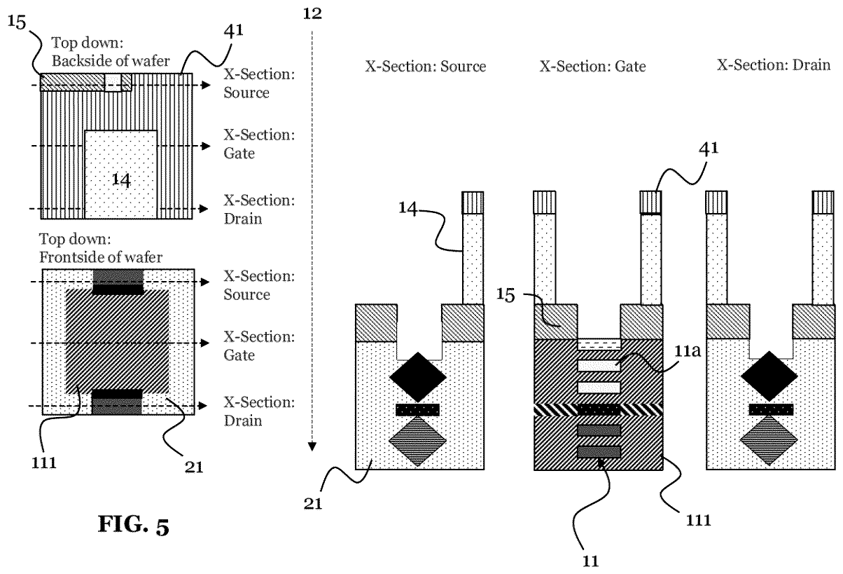

FIG. 5 illustrates a third step of the first example processing sequence. In the third step, etching is performed using the first lithography mask material 41 applied in the second step. The etching is accordingly selective into the backside of the substrate 14. The sacrificial plug 27 in the STI 15 is also etched, and the etching is stopped at the GAA structure 111 and/or at a bottom dielectric isolation (BDI) 24.

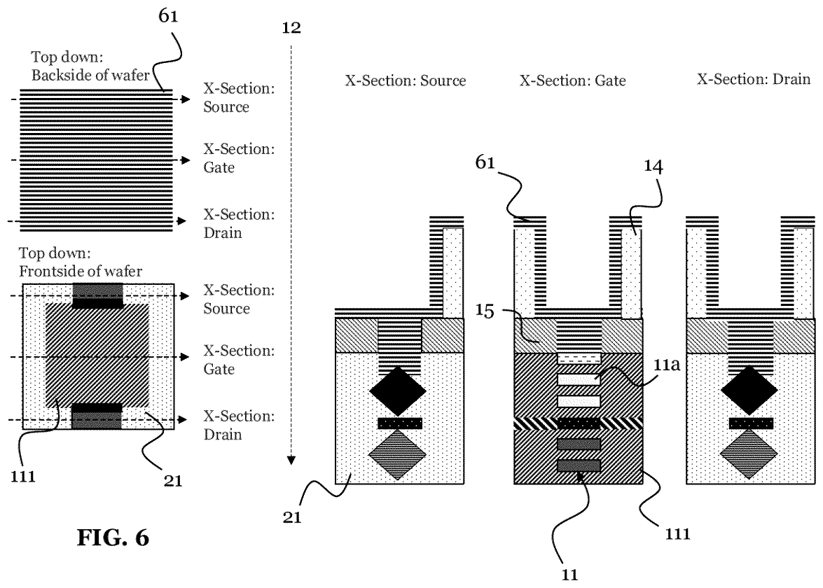

FIG. 6 illustrates a fourth step of the first example processing sequence. In the fourth step, a metal 61 is deposited into the spaces created by the previous etching of the substrate 14 and the sacrificial plug 27. The metal 61 may be used, for instance, as a first metal 13a of the storage capacitor 13.

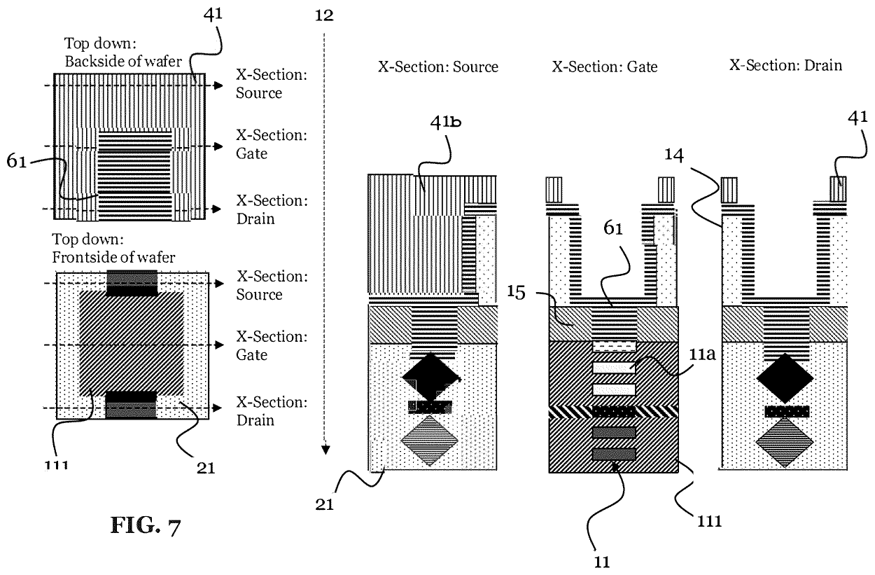

FIG. 7 illustrates a fifth step of the first example processing sequence. In the fifth step, a second lithography is performed, wherein a second mask material 41b is applied to the backside of the substrate 14. This lithography step prepares, for example, for forming a dielectric material and a second metal of the storage capacitor 13, and for forming a bit line contact in the second region.

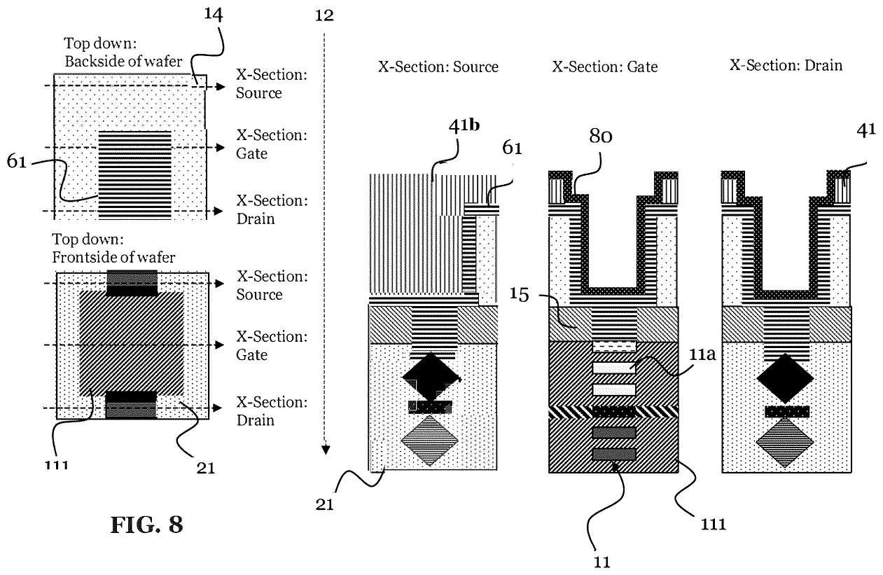

FIG. 8 illustrates a sixth step of the first example processing sequence. In the sixth step, a dielectric material 80 is deposited. The deposition is formed on the second mask material 41b. The dielectric material 80 may be used, for instance, as a dielectric material 13c of the storage capacitor 13.

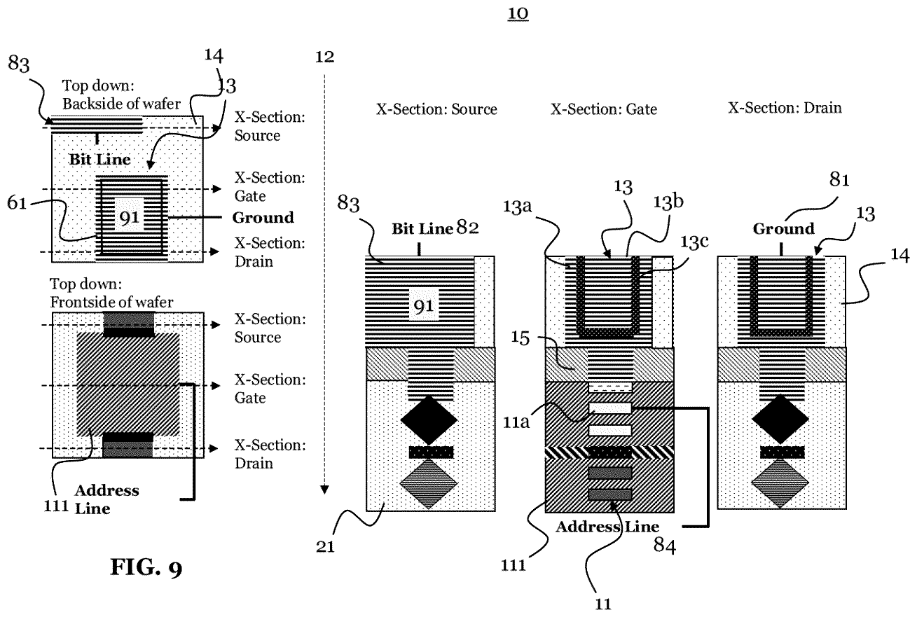

FIG. 9 shows a seventh step of the first example processing sequence. In the seventh step, a bulk metal deposition is performed. A bulk metal 91 is used as the second metal 13b of the storage capacitor 13. As a result, the storage capacitor 13 comprising the first metal 13a, the second metal 13b, and the dielectric material 13c separating the two metals 13a, 13b is completed. The bulk metal 91 may also be used to form a bit line contact 83 in the second region. FIG. 9 also shows that the second metal 13b of the storage capacitor 13 is connected to a ground line 81. Further a bit line 82 is connected to the bit line contact 83. Further, an address line 84 is connected to a gate of the one transistor 11a. At least a part of the address line 84 is arranged above the first region along the stacking direction 12, i.e., the gate connection is formed from the frontside of the substrate 14.

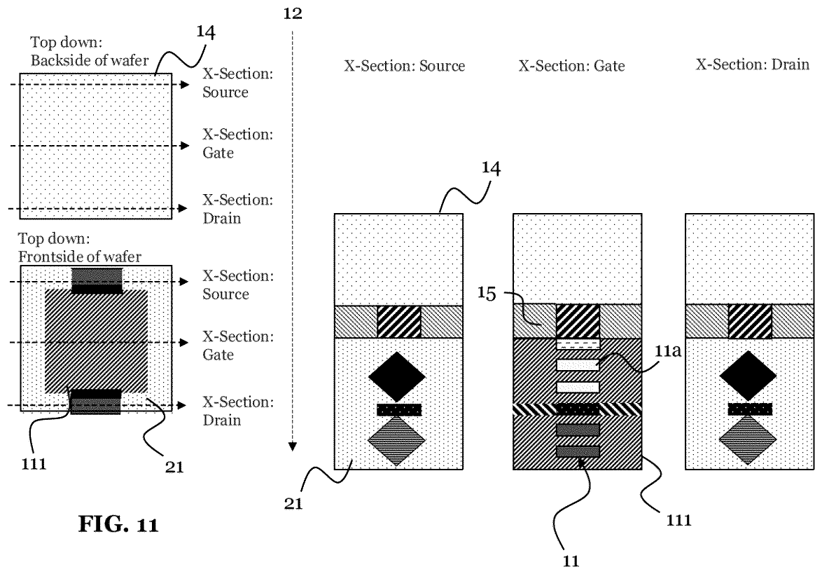

FIG. 10 illustrates an initial structure for starting the second example processing sequence. The initial structure is shown in various views, particularly, in a top-down view of the backside of the substrate 14, in a top-down view of the front side of the substrate 14, in a view along a X-section through the source, in a view along a X-section through the gate, and in a view along the X-section through the drain. The same views are used in the FIGS. 11-17 to illustrate the second example processing sequence. The initial structure of FIG. 10 corresponds more or less to the one shown in FIG. 2, so that a detailed description is not repeated.

FIG. 11 illustrates a first step of the second example processing sequence. In the first step, the initial structure is flipped, and then a partial polish is performed on the backside of the substrate 14.

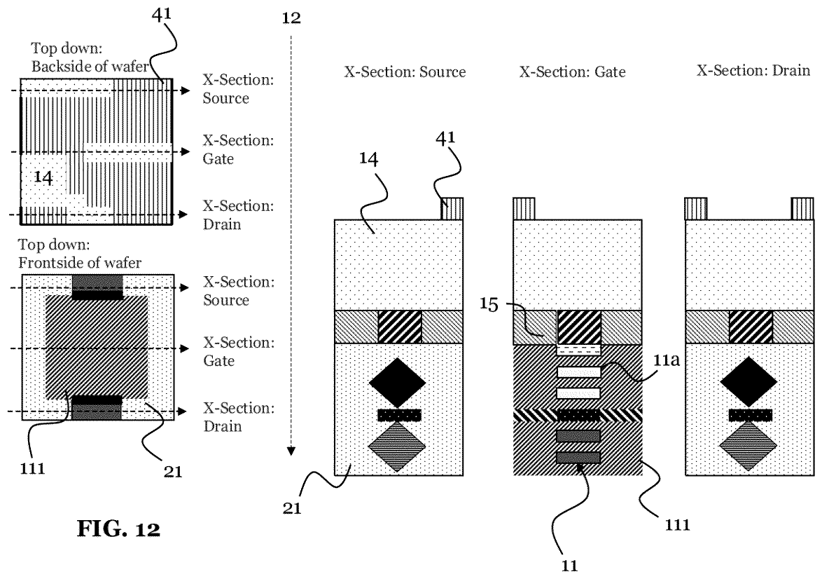

FIG. 12 illustrates a second step of the second example processing sequence. In this second step, lithography is performed, for example, for the purpose of processing a source, gate, and drain contact of the one transistor 11a in a self-aligned manner using the sacrificial plug 27, as described above. A first mask material 41 is selectively applied during the lithography, wherein the first mask material 41 is applied to the backside of the substrate 14. The lithography in the second example processing sequence differs from the lithography of the first example processing sequence illustrated in FIG. 4.

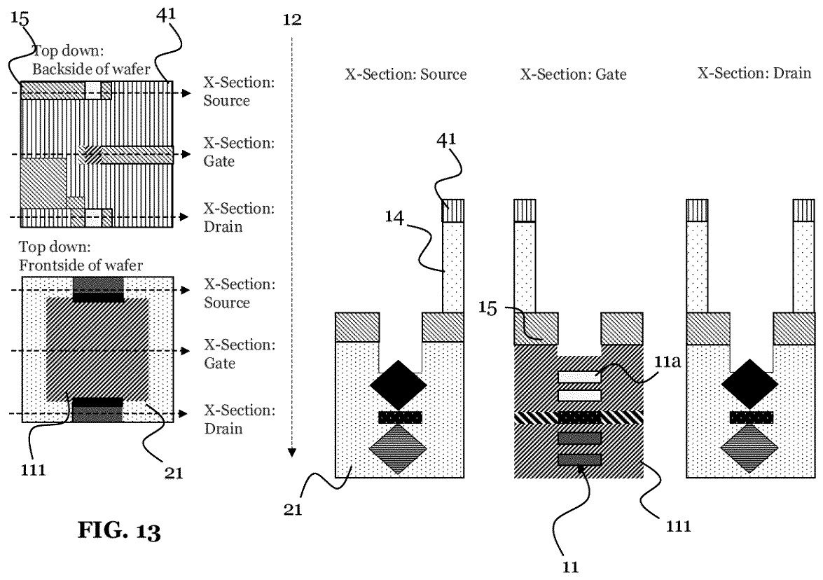

FIG. 13 illustrates a third step of the second example processing sequence. In the third step, etching is performed using the first lithography mask material 41. The etching is accordingly selective into the backside of the substrate 14. The sacrificial plug 27 in the STI 15 is also etched, and the etching is stopped at the GAA structure 111 and/or at a bottom dielectric isolation (BDI) 24.

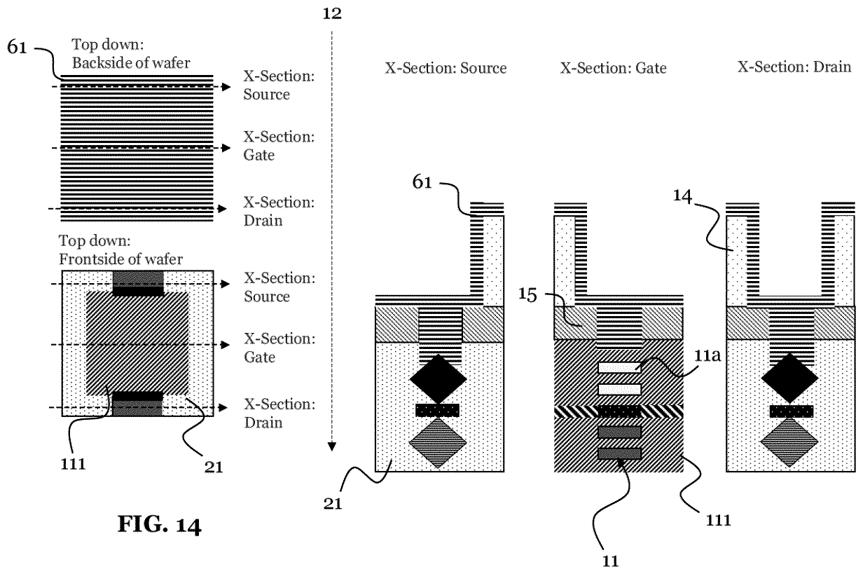

FIG. 14 illustrates a fourth step of the second example processing sequence. In the fourth step, a metal 61 is deposited into the spaces created by the etching of the substrate 14 and the sacrificial plug 27, respectively. The metal 61 may be used, for instance, as a first metal 13a of the storage capacitor 13, and for forming a bit line contact and gate contact in the second region.

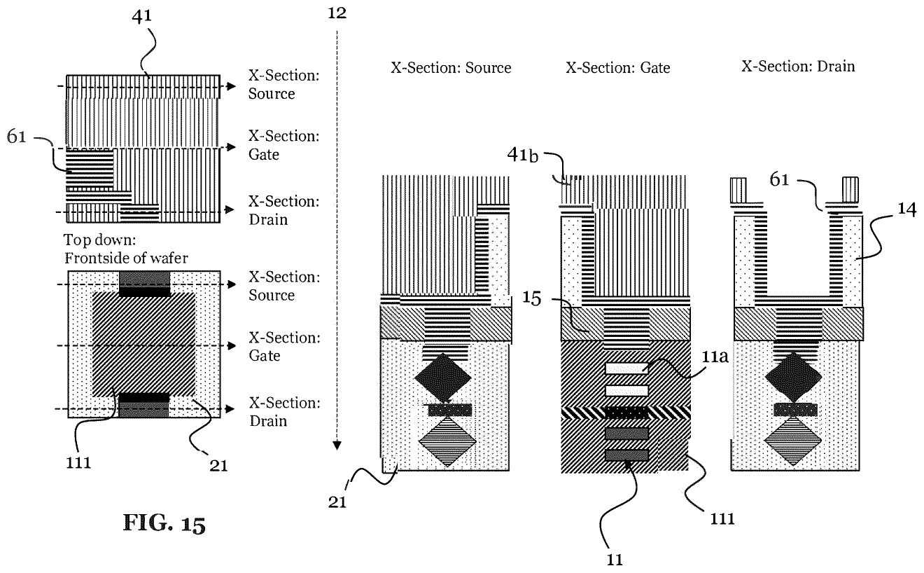

FIG. 15 illustrates a fifth step of the second example processing sequence. In the fifth step, a second lithography is performed, wherein a second mask material 41b is applied to the backside of the substrate 14. This lithography prepares, for example, for forming the dielectric material and a second metal of the storage capacitor 13, and for forming a bit line contact and gate contact in the second region. The lithography in the second example processing sequence differs from the lithography of the first example processing sequence illustrated in FIG. 7. While in FIG. 7 the lithography opens the mask over the gate and drain, in FIG. 15 the mask over the gate is not opened in order to further use it as contact to an address line.

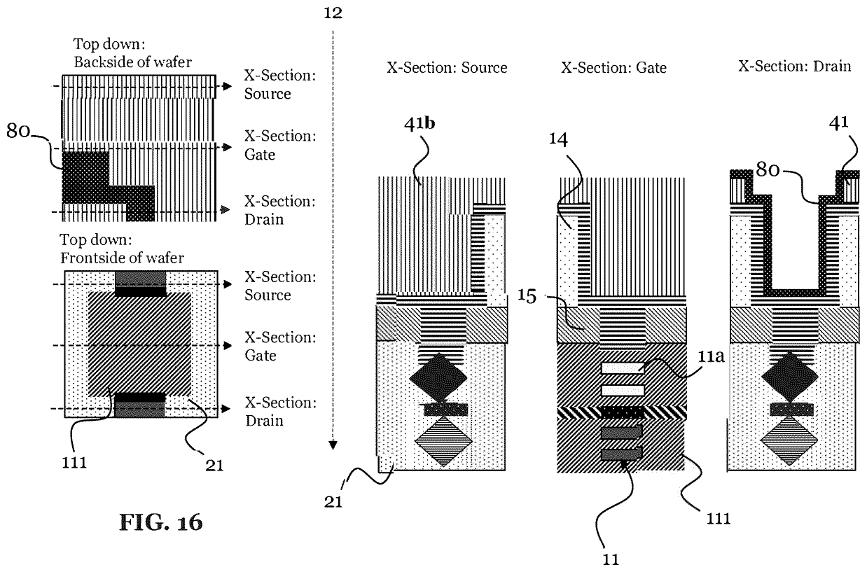

FIG. 16 illustrates a sixth step of the second example processing sequence. In the sixth step, a dielectric material 80 is deposited. The dielectric material 80 may be used, for example, as a dielectric material 13c of the storage capacitor 13. In this example, the dielectric material 80 is not formed on the second mask material 41b.

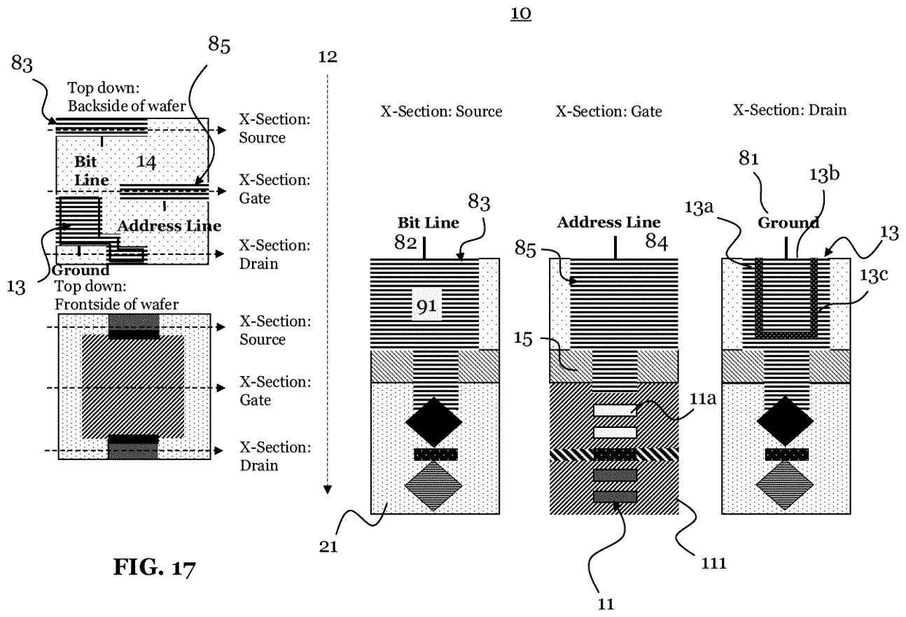

FIG. 17 illustrates a seventh step of the second example processing sequence. In the seventh step, a bulk metal deposition is performed. A bulk metal 91 is used as the second metal 13b of the storage capacitor 13. As a result, the storage capacitor 13 comprising the first metal 13a, the second metal 13b, and the dielectric material 13c separating the two metals 13a, 13b is completed. The bulk metal 91 may also be used to form a bit line contact 83 in the substrate 14. The bulk metal 91 may also be used to form a gate contact 85 in the second region. The gate contact 85 is connected to a gate of the one transistor 11a. FIG. 17 also shows that the second metal 13c of the storage capacitor 13 is connected to a ground line 81. Further a bit line 82 is connected to the bit line contact 83. Further, an address line 84 is connected to a gate contact 85. The second region is arranged above at least a part of the address line 84 along the stacking direction 12. Thus, all connections—the bit line connection, gate connection, and ground connection—are formed from the backside of the substrate 14 in the second example processing sequence.

FIG. 18 illustrates exemplary implementations and explanations of elements of the DRAM device 10 according to this disclosure. The substrate/wafer 14 may be made of silicon. The GAA structure 111 may be made of HKMG+W. The stacked transistors 11 may be nanosheet transistors (i.e. may have nanosheet channels).

FIG. 19 illustrates a schematic circuit of the DRAM cell, and illustrates how the gate connections, ground connections, and bit line connections are made to the address line 84, ground line 81, and bit line 82, respectively, in the configurations shown in FIGS. 9 and 17, to form the DRAM cell.

In summary, the disclosed technology relates to a DRAM device 10 and exemplary fabrication sequences for forming the DRAM device 10. In some embodiments, the DRAM device may include a DRAM integrated with a logic circuit. For instance, a storage capacitor of the DRAM may be embedded directly below a CFET structure, and a selected transistor of the CFET structure may be connected to the storage capacitor to form a DRAM cell.

In the claims as well as in the description of this disclosure, the word ‘comprising’ does not exclude other elements or steps and the indefinite article ‘a’ or ‘an’ does not exclude a plurality. A single element may fulfill the functions of several entities or items recited in the claims. The mere fact that certain measures are recited in the mutual different dependent claims does not indicate that a combination of these measures cannot be used in an advantageous implementation.

What is claimed is:

1. An integrated dynamic random access memory (DRAM) device including a DRAM and a logic circuit configured to control the DRAM, the DRAM device comprising:
a plurality of stacked transistors arranged in a first region of the DRAM device, the stacked transistors stacked in a stacking direction; and
a storage capacitor arranged in a second region of the DRAM device, wherein the first region is positioned above the second region along the stacking direction;
wherein one of the plurality of stacked transistors is connected to the storage capacitor to form a DRAM cell of the DRAM, and
wherein the others of the plurality of stacked transistors form at least a portion of the logic circuit.

2. The DRAM device according to claim 1, wherein the second region is a substrate layer of the DRAM device, and the storage capacitor is embedded within the substrate layer.

3. The DRAM device according to claim 1, wherein the one of the plurality of stacked transistors is connected by a drain thereof to a first metal structure of the storage capacitor.

4. The DRAM device according to claim 3, wherein the storage capacitor further comprises:
a second metal structure, wherein the first metal structure is arranged above the second metal structure along the stacking direction; and
a dielectric layer separating and isolating the second metal structure from the first metal structure.

5. The DRAM device according to claim 4, wherein the second metal structure is connected to a ground line of the DRAM device, and the second region is arranged above the ground line along the stacking direction.

6. The DRAM device according to claim 1, further comprising:
a bit line contact formed in the second region, wherein the bit line contact is connected to a source of the one of the plurality of stacked transistors and is connected to a bit line of the DRAM device,
wherein the second region is arranged above at least a part of the bit line along the stacking direction.

7. The DRAM device according to claim 1, wherein a gate of the one of the plurality of stacked transistors is connected to an address line of the DRAM device.

8. The DRAM device according to claim 7, wherein at least a part of the address line is arranged above the first region along the stacking direction.

9. The DRAM device according to claim 7, further comprising
a gate contact arranged in the second region, wherein the gate contact is connected to the gate of the one of the plurality of stacked transistors and is connected to the address line,
wherein the second region is arranged above at least a part of the address line along the stacking direction.

10. The DRAM device according to claim 1, wherein the storage capacitor is formed self-aligned with the one of the plurality of stacked transistors.

11. The DRAM device according to claim 1, wherein the first region and the second region are monolithically integrated.

12. The DRAM device according to claim 1, wherein the stacked transistors are nanosheet transistors.

13. The DRAM device according to claim 1, wherein the remaining one or ones of the plurality of stacked transistors comprise a set of n-type transistors and a set of p-type transistors of a complementary field effect transistor (CFET).

14. The DRAM device according to claim 1, wherein the stacked transistors are formed by stacked transistor channels, and wherein the stacked transistors are surrounded by a gate-all-around (GAA) structure.

15. A method for fabricating an integrated dynamic random access memory (DRAM) device including a DRAM and a logic circuit configured to control the DRAM, the method comprising:
forming a plurality of stacked transistors in a first region of the DRAM device, the stacked transistors stacked in a stacking direction;
forming a storage capacitor in a second region of the DRAM device, wherein the first region is formed above the second region along the stacking direction;
wherein one of the plurality of stacked transistors is connected to the storage capacitor to form a DRAM cell of the DRAM; and
wherein the others of the plurality of stacked transistors form at least a portion of the logic circuit.

16. The method according to claim 15, wherein
the second region is a substrate layer,
the first region is formed on a front surface of and above the substrate layer, and
the storage capacitor is processed into the substrate layer from a back surface of the substrate layer.

17. The method according to claim 15, wherein the storage capacitor is formed self-aligned with the one of the plurality of stacked transistors, by etching a sacrificial plug adjacent to a source and a drain of the transistor, and by filling a first metal of the storage capacitor into a space created by the etching of the sacrificial plug.

18. The method according to claim 17, wherein the storage capacitor is formed in proximate to the one of the plurality of stacked transistors, such that the first metal is connected to the source and the drain of the one of the plurality of stacked transistors without vias.

19. The method according to claim 15, further comprising forming a bit line contact in the second region, wherein the bit line contact is connected to a source of the one of the plurality of stacked transistors.

20. The method according to claim 15, further comprising forming a gate contact in the second region, wherein the gate contact, is connected to a gate of the one of the plurality of stacked transistors.
